(19) United States
(12) Patent Application Publication
(10) Pub. No.: US 2026/0164655 A1
(43) Pub. Date: Jun. 11, 2026

(54) SEMICONDUCTOR MEMORY DEVICE

(71) Applicant: Kioxia Corporation, Tokyo (JP)

(72) Inventor: Yoshiro SHIMOJO, Nagoya (JP)

(73) Assignee: Kioxia Corporation, Tokyo (JP)

(21) Appl. No.: 19/324,301

(22) Filed: Sep. 10, 2025

(30) Foreign Application Priority Data
Dec. 9, 2024 (JP) 2024-214713

(51) Int. Cl. H10B 41/35; H10B 41/10; H10B 41/27

(52) U.S. Cl. CPC H10B 41/35; H10B 41/10; H10B 41/27

(57) ABSTRACT

According to one embodiment, a semiconductor memory device comprising: two first conductive pillars extending in a first direction and aligned in a second direction; first and second semiconductor layers arranged in a first plane and sandwiching the two first conductive pillars in a third direction; a first insulator arranged between the two first conductive pillars and insulating them from each other, and further insulating the first and the second semiconductor layers from each other in the first plane; and storage films arranged in the first plane between the two first conductive pillars and the first and the second semiconductor layers, respectively, wherein the first insulator includes a portion that is in contact with the first and the second semiconductor layers in the first plane, and that is formed in a concentric circular or concentric elliptical shape having a center between the two first conductive pillars.

### CROSS-REFERENCE TO RELATED APPLICATIONS

This application is based upon and claims the benefit of priority from Japanese Patent Application No. 2024-214713, filed Dec. 9, 2024, the entire contents of which are incorporated herein by reference.

### FIELD

Embodiments described herein relate generally to a

### BACKGROUND

A NAND flash memory is known as a semiconductor memory device capable of storing data in a non-volatile manner. In a NAND flash memory, a three-dimensional memory structure may be adopted for high integration and large capacity.

### BRIEF DESCRIPTION OF THE DRAWINGS

FIG. 1 is a block diagram illustrating an example of the configuration of a memory system according to an embodiment.

FIG. 2 is a circuit diagram illustrating an example of the circuit configuration of a memory cell array provided in a semiconductor memory device according to the embodiment.

FIG. 3 is a plan view illustrating an example of the planar layout of the memory cell array provided in the semiconductor memory device according to the embodiment.

FIG. 4 is a plan view illustrating an example of the planar layout of a memory cell region of the memory cell array provided in the semiconductor memory device according to the embodiment.

FIG. 5 is a cross-sectional view taken along line V-V in FIG. 4, and illustrates an example of the cross-sectional structure in the memory cell region of the memory cell array provided in the semiconductor memory device according to the embodiment.

FIG. 6 is a cross-sectional view taken along line VI-VI in FIG. 4, and illustrates an example of the cross-sectional structure in the memory cell region of the memory cell array provided in the semiconductor memory device according to the embodiment.

FIG. 7 is a cross-sectional view taken along line VII-VII in FIG. 6, and illustrates an example of the cross-sectional structure of a conductive pillar provided in the semiconductor memory device according to the embodiment.

FIG. 8 is a cross-sectional view taken along line VIII-VIII in FIG. 6, and illustrates an example of the cross-sectional structure of the conductive pillar provided in the semiconductor memory device according to the embodiment.

FIG. 9 is a cross-sectional view taken along line IX-IX in FIG. 6, and illustrates an example of the cross-sectional structure of the conductive pillar provided in the semiconductor memory device according to the embodiment.

FIG. 10 is a flowchart illustrating an example of a manufacturing process of the memory cell region of the memory cell array provided in the semiconductor memory device according to the embodiment.

FIG. 11 is a cross-sectional view illustrating an example of the cross-sectional structure of the memory cell region during the manufacturing process of the memory cell array provided in the semiconductor memory device according to the embodiment.

FIG. 12 is a plan view illustrating an example of the planar layout of the memory cell region during the manufacturing process of the memory cell array provided in the semiconductor memory device according to the embodiment.

FIG. 13 is a cross-sectional view illustrating an example of the cross-sectional structure of the memory cell region during the manufacturing process of the memory cell array provided in the semiconductor memory device according to the embodiment.

FIG. 14 is a cross-sectional view illustrating an example of the cross-sectional structure of the memory cell region during the manufacturing process of the memory cell array provided in the semiconductor memory device according to the embodiment.

FIG. 15 is a cross-sectional view illustrating an example of the cross-sectional structure of the memory cell region during the manufacturing process of the memory cell array provided in the semiconductor memory device according to the embodiment.

FIG. 16 is a cross-sectional view illustrating an example of the cross-sectional structure of the memory cell region during the manufacturing process of the memory cell array provided in the semiconductor memory device according to the embodiment.

FIG. 17 is a plan view illustrating an example of the planar layout of the memory cell region during the manufacturing process of the memory cell array provided in the semiconductor memory device according to the embodiment.

FIG. 18 is a cross-sectional view illustrating an example of the cross-sectional structure of the memory cell region during the manufacturing process of the memory cell array provided in the semiconductor memory device according to the embodiment.

FIG. 19 is a cross-sectional view illustrating an example of the cross-sectional structure of the memory cell region during the manufacturing process of the memory cell array provided in the semiconductor memory device according to the embodiment.

FIG. 20 is a cross-sectional view illustrating an example of the cross-sectional structure of the memory cell region during the manufacturing process of the memory cell array provided in the semiconductor memory device according to the embodiment.

FIG. 21 is a cross-sectional view illustrating an example of the cross-sectional structure of the memory cell region during the manufacturing process of the memory cell array provided in the semiconductor memory device according to the embodiment.

FIG. 22 is a cross-sectional view illustrating an example of the cross-sectional structure of the memory cell region during the manufacturing process of the memory cell array provided in the semiconductor memory device according to the embodiment.

FIG. 23 is a cross-sectional view illustrating an example of the cross-sectional structure of the memory cell region during the manufacturing process of the memory cell array provided in the semiconductor memory device according to the embodiment.

FIG. 24 is a cross-sectional view illustrating an example of the cross-sectional structure of the memory cell region during the manufacturing process of the memory cell array provided in the semiconductor memory device according to the embodiment.

FIG. 25 is a cross-sectional view illustrating an example of the cross-sectional structure of the memory cell region during the manufacturing process of the memory cell array provided in the semiconductor memory device according to the embodiment.

FIG. 26 is a plan view illustrating an example of a planar layout of a memory cell region of a memory cell array provided in a semiconductor memory device according to a first modification of the embodiment.

FIG. 27 is a cross-sectional view illustrating an example of a cross-sectional structure of a semiconductor memory device according to a second modification of the embodiment.

FIG. 28 is a cross-sectional view illustrating an example of the cross-sectional structure of a word line switch provided in the semiconductor memory device according to the second modification of the embodiment.

FIG. 29 is a perspective view illustrating an example of the structure of the word line switch provided in the semiconductor memory device according to the second modification of the embodiment.

### DETAILED DESCRIPTION

In general, according to one embodiment, a semiconductor memory device includes: two first conductive pillars that extend in a first direction intersecting a substrate and that are aligned in a second direction intersecting the first direction; a first semiconductor layer and a second semiconductor layer that are arranged in a first plane parallel to the substrate and that sandwich the two first conductive pillars in a third direction intersecting both the first direction and the second direction; a first insulator that is arranged between the two first conductive pillars and that insulates the two first conductive pillars from each other, and further insulates the first semiconductor layer and the second semiconductor layer from each other in the first plane; two first charge storage films that are arranged in the first plane between the two first conductive pillars and the first semiconductor layer, respectively; and two second charge storage films that are arranged in the first plane between the two first conductive pillars and the second semiconductor layer, respectively, wherein the first insulator includes a portion that is in contact with the first semiconductor layer and the second semiconductor layer in the first plane, and that is formed in a concentric circular or concentric elliptical shape having a center between the two first conductive pillars.

Embodiments will be described below with reference to the accompanying drawings. The drawings are schematic, and the dimensions and scales in the drawings do not necessarily correspond to those of actual products. In the description below, components having the same functions and configurations will be denoted by the same reference symbols. Where elements having similar configurations are to be specifically distinguished from each other, different letters or numerals may be appended to the same reference numeral.

In the description below, in a case where a first element is described as being “coupled” to a second element, this includes not only the case where the first element is indirectly coupled to the second element via an intermediate element that is conductive either at all times or at selected times, but also the case where the first element is directly coupled to the second element without an intermediate element.

### 1. Configuration

### 1.1 Memory System

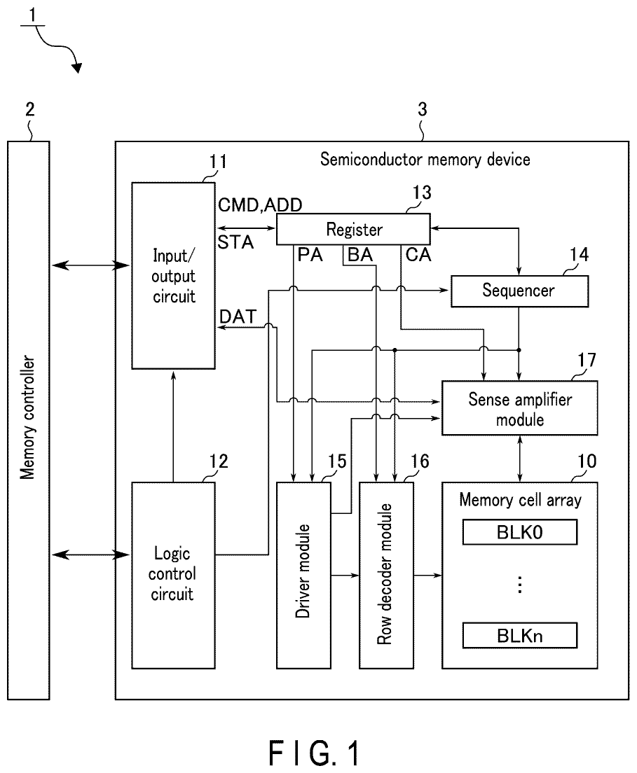

A semiconductor memory device according to an embodiment will be described. FIG. 1 is a block diagram illustrating an example of the configuration of a memory system according to the embodiment. The memory system 1 is a memory device configured to be coupled to an external host device (not shown). The memory system 1 is, for example, a memory card such as an SD™ card, a universal flash storage (UFS), or a solid-state drive (SSD). The memory system 1 includes a memory controller 2 and a semiconductor memory device 3.

The memory controller 2 is configured, for example, with an integrated circuit such as a system on a chip (SoC). The memory controller 2 controls the semiconductor memory device 3, based on a request from the external host device. Specifically, the memory controller 2 writes data requested by the external host device to the semiconductor memory device 3. The memory controller 2 also reads data requested by the external host device from the semiconductor memory device 3 and outputs it to the external host device.

The semiconductor memory device 3 is, for example, a NAND flash memory capable of storing data in a non-volatile manner.

The communication between the memory controller 2 and the semiconductor memory device 3 conforms, for example, to the single data rate (SDR) interface, the toggle double data rate (DDR) interface, or the open NAND flash interface (ONFI).

### 1.2 Semiconductor Memory Device

Next, with reference to the block diagram shown in FIG. 1, the internal configuration of the semiconductor memory device 3 according to the present embodiment will be described. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 is a set of memory cell transistors and components coupled to the memory cell transistors. The memory cell array 10 includes a plurality of blocks BLK0 to BLKn (n is an integer of 1 or more). A block BLK is a set of memory cell transistors capable of storing data in a non-volatile manner. The block BLK is used, for example, as an erase unit when data stored in the memory cell transistors is erased. The memory cell array 10 includes a plurality of bit lines and a plurality of word lines. Each memory cell transistor is associated, for example, with a combination of one bit line and one word line. A detailed configuration the memory cell array 10 will be described later.

The input/output circuit 11 is an interface circuit responsible for transmitting and receiving input/output signals to and from the memory controller 2. The input/output signals include, for example, data DAT, a command CMD, address information ADD, and status information STA. The input/output circuit 11 inputs and outputs the data DAT between the sense amplifier module 17 and the memory controller 2. The input/output circuit 11 outputs each of the command CMD and address information ADD transferred from the memory controller 2 to the register 13. The input/output circuit 11 outputs the status information STA transferred from the register 13 to the memory controller 2.

The logic control circuit 12 receives a control signal input from the memory controller 2. The logic control circuit 12 controls each of the input/output circuit 11 and the sequencer 14, based on the control signal. For example, the logic control circuit 12 notifies the input/output circuit 11 that the input/output signal received by the input/output circuit 11 is a command CMD, address information ADD, or the like. The logic control circuit 12 instructs the input/output circuit 11 to input or output an input/output signal. The logic control circuit 12 controls the sequencer 14 to enable the semiconductor memory device 3. The logic control circuit 12 also outputs a signal indicating whether the semiconductor memory device 3 is in a ready state or a busy state to the memory controller 2.

The register 13 temporarily stores the command CMD, the address information ADD, and the status information STA. The command CMD includes, for example, instructions for causing the sequencer 14 to execute a read operation, a write operation, an erase operation, etc. The address information ADD includes, for example, a block address BA, a page address PA, and a column address CA. For example, the block address BA, the page address PA, and the column address CA are used to select a block BLK, a word line and a bit line, respectively. The status information STA is updated based on the control of the sequencer 14, and is transferred to the input/output circuit 11.

The sequencer 14 controls the overall operation of the semiconductor memory device 3. For example, the sequencer 14 controls the driver module 15, the row decoder module 16, and the sense amplifier module 17, based on the command CMD stored in the register 13, to execute a read operation, a write operation, an erase operation, etc.

The driver module 15 generates a plurality of voltages of different magnitudes used in a read operation, a write operation, an erase operation, etc. The driver module 15 supplies the generated voltages to the row decoder module 16 and the sense amplifier module 17, etc. The driver module 15 also applies the generated voltage to a signal line corresponding to a word line that is selected, for example, based on a page address PA stored in the register 13.

The row decoder module 16 selects, for example, a corresponding block BLK in the memory cell array 10, based on a block address BA stored in the register 13. The row decoder module 16 transfers, for example, a signal line voltage applied by the driver module 15 to the selected word line in the selected block BLK.

The sense amplifier module 17 includes a sense amplifier capable of determining data, based on the voltage of an associated bit line, a latch circuit for temporarily storing data, etc. In a write operation, the sense amplifier module 17 applies a desired voltage to each bit line in accordance with write data DAT received from the input/output circuit 11. In a read operation, the sense amplifier module 17 determines data stored in the memory cell transistor, based on the magnitude of the voltage on the bit line. Then, the sense amplifier module 17 transfers the determination result to the input/output circuit 11 as read data DAT.

### 1.3 Circuit Configuration of Memory Cell Array

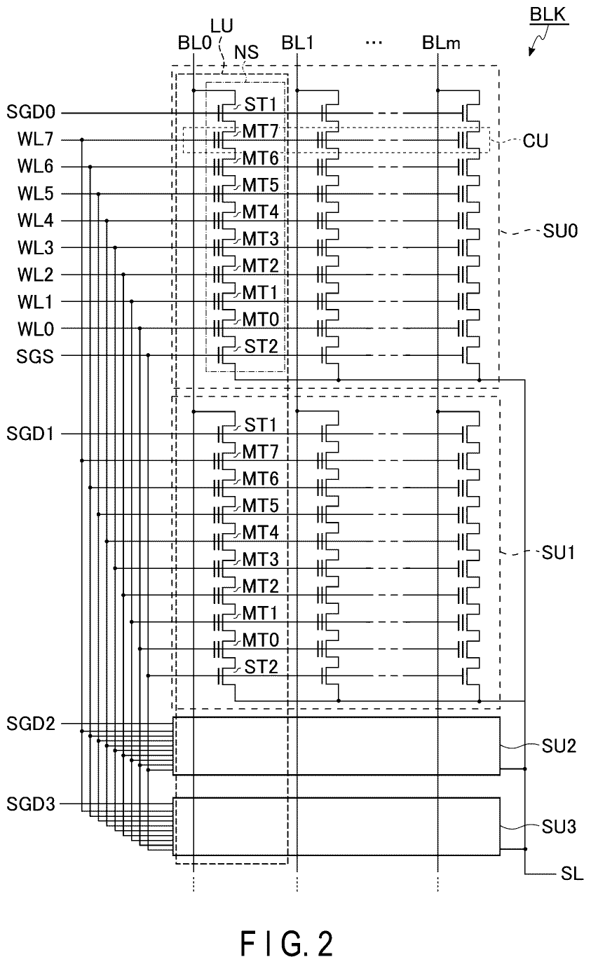

FIG. 2 is a circuit diagram illustrating an example of the circuit configuration of a memory cell array provided in the semiconductor memory device according to the embodiment. FIG. 2 shows one block BLK. The block BLK includes, for example, four string units SU0 to SU3.

Each string unit SU includes a plurality of NAND strings NS associated with bit lines BL0 to BLm (m is an integer equal to or greater than 1), respectively. Each NAND string NS includes, for example, eight memory cell transistors MT0 to MT7 and select transistors ST1 and ST2. Each memory cell transistor MT includes a control gate and a charge storage film, and stores data in a non-volatile manner, based on the amount of charge in the charge storage film. Each of the select transistors ST1 and ST2 is used for selecting a string unit SU during various operations.

In each NAND string NS, the memory cell transistors MT0 to MT7 are coupled in series in this order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to word lines WL0 to WL7, respectively. The gates of the select transistors ST1 in the string units SU0 to SU3 are coupled to select gate lines SGD0 to SGD3, respectively. The gates of the select transistors ST2 are coupled to a select gate line SGS.

Different column addresses are assigned to the bit lines BL0 to BLm. In the plurality of blocks BLK, each bit line BL is shared by the NAND strings NS that are assigned the same column address CA. The word lines WL0 to WL7 are provided for each block BLK. The source line SL is shared, for example, by the plurality of blocks BLK.

A set of memory cell transistors MT coupled to a common word line WL within a single string unit SU are referred to, for example, as a cell unit CU. For example, the storage capacity of a cell unit CU, which includes memory cell transistors MT each storing 1-bit data, is defined as “1 page of data.” The cell unit CU may have a storage capacity of two or more pages of data in accordance with the number of bits of data stored in each memory cell transistor MT.

A set of memory cell transistors MT coupled to a common bit line BL within a single block BLK is referred to a layer unit LU, for example. One layer unit LU includes a plurality of NAND strings NS corresponding in number to the string units SU included in one block BLK. In the example shown in FIG. 2, one layer unit LU includes four NAND strings NS. Each NAND string NS included in one layer unit LU belongs to one of the string units SU0 to SU3, respectively.

It should be noted that the circuit configuration of the memory cell array 10 provided in the semiconductor memory device 3 according to the present embodiment is not limited to the above description. For example, the number of string units SU included in each block BLK may be designed to be an arbitrary number. The number of memory cell transistors MT included in each NAND string NS and the number of select transistors ST1 and ST2 may be designed to be arbitrary numbers.

### 1.4 Structure of Memory Cell Array

### 1.4.1 Overview

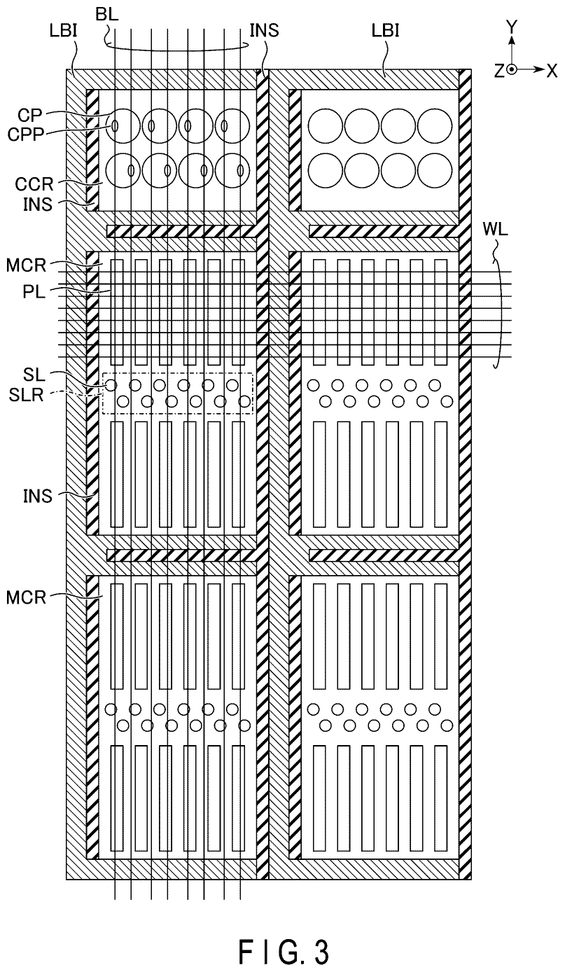

FIG. 3 is a plan view illustrating an example of the planar layout of the memory cell array provided in the semiconductor memory device according to the embodiment. As shown in FIG. 3, the memory cell array 10 includes a plurality of bit lines BL, a plurality of word lines WL, a plurality of memory cell regions MCR, a plurality of contact regions CCR, a plurality of interconnect layers LBI, and a plurality of insulators INS.

The plurality of bit lines BL and the plurality of word lines WL extend in a direction parallel to the semiconductor substrate, and cross each other. In the description below, the direction in which the word lines WL extend is defined as an X direction, and the direction in which the bit lines BL extend is defined as a Y direction. The direction perpendicular to the semiconductor substrate is defined as a Z direction, and the direction in which the bit lines BL and the word lines WL are formed with respect to the semiconductor substrate is defined as an upward direction. The direction opposite to the upward direction is defined as a downward direction.

The memory cell array 10 has a structure in which a plurality of semiconductor layers are stacked with spacing between them in the Z direction. The number of stacked semiconductor layers corresponds to the number of bit lines BL provided in one block BLK.

The memory cell region MCR is a region in which memory cell transistors MT and their related structures are provided. The plurality of memory cell regions MCR are arranged in columns in the Y direction via the interconnect layers LBI and the insulators INS, which will be described later. The columns of the memory cell regions MCR are arranged, with a gap therebetween in the X direction.

Each memory cell region MCR includes a plurality of pillar columns PL and a plurality of source line regions SLR. Each pillar column PL is a column including a plurality of pillars aligned in the Y direction in a plan view. The plurality of pillar columns PL are arranged in the X direction. A plurality of source lines SL are provided in each source line region SLR. The plurality of source lines SL are arranged in such a manner as to penetrate the stacked semiconductor layers in the Z direction. Each memory cell region MCR has a shape that is approximately symmetrical in the Y direction, with the source line region SLR as the axis of symmetry. The detailed configuration of the memory cell region MCR will be described later.

The contact regions CCR are regions used for coupling each stacked semiconductor layer to the plurality of bit lines BL. For example, one contact region CCR is provided for each of the plurality of memory cell regions MCR arranged in the Y direction. For example, the contact regions CCR are positioned so as to be aligned with the plurality of memory cell regions MCR in the Y direction.

A plurality of conductive pillars CP are provided in the contact region CCR. Each conductive pillar CP is provided corresponding to each of the stacked semiconductor layers, is electrically coupled to the corresponding semiconductor layer, and is electrically insulated from the other semiconductor layers. Each conductive pillar CP is coupled to the corresponding bit line BL via a contact CPP.

The plurality of interconnect layers LBI couple the semiconductor layers in the memory cell regions MCR, which are arranged in columns in the Y direction at the same height, to the semiconductor layers in the contact regions CCR. Each interconnect layer LBI has a first portion extending in the Y direction and a plurality of second portions extending in the X direction. The first portion of each interconnect layer LBI is provided in the X direction along one column of the memory cell region MCR. In the example shown in FIG. 3, the first portion of each interconnect layer LBI is located on the left side of the column of the memory cell regions MCR. The second portions of each interconnect layer LBI are in contact with the first portion of the interconnect layer LBI at their ends, and are arranged between the memory cell regions MCR and the contact regions CCR, which are aligned in the Y direction. In other words, the second portions of each interconnect layer LBI separate the plurality of memory cell regions MCR and the plurality of the contact regions CCR. The plurality of interconnect layers LBI include, for example, titanium nitride (TiN).

The plurality of insulators INS are used to insulate the respective regions. For example, the plurality of insulators INS insulate the first portions of the interconnect layers LBI from the interconnect layers in the memory cell regions MCR in the X direction. The plurality of insulators INS insulate the first portions of the interconnect layers LBI from the semiconductor layers in the contact region CCR in the X direction.

### 1.4.2 Memory Cell Region

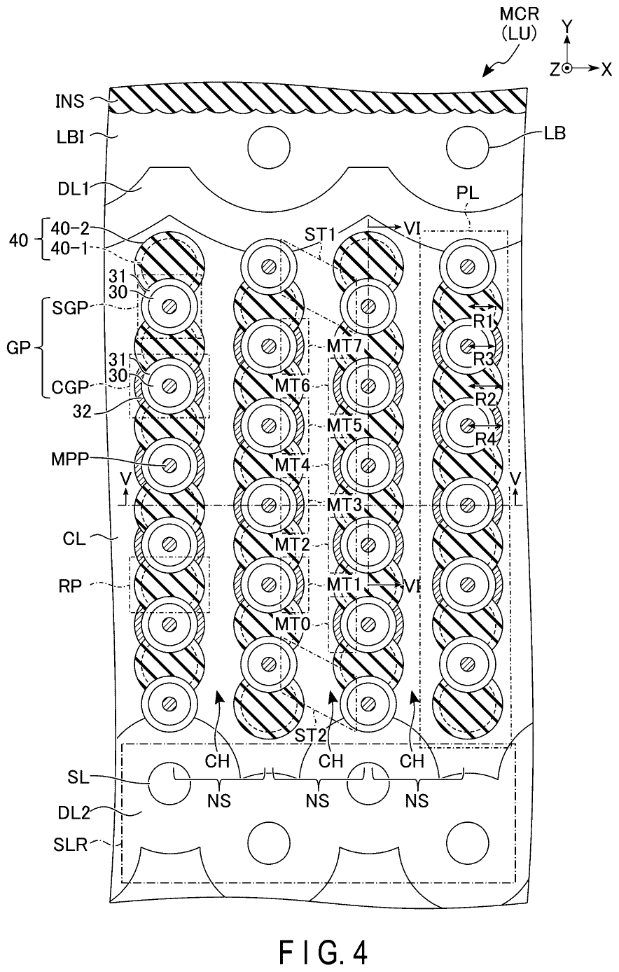

FIG. 4 is a plan view illustrating an example of the planar layout of the memory cell region of the memory cell array provided in the semiconductor memory device according to the embodiment. As shown in FIG. 4, the memory cell region in one semiconductor layer functions as a layer unit LU. In the memory cell region MCR, the memory cell array 10 includes a channel layer CL, diffusion layers DL1 and DL2, a plurality of conductive pillars GP, a plurality of insulating pillars RP and LB, and a plurality of contacts MPP.

The channel layer CL is a semiconductor layer made of a semiconductor that extends in the XY plane. The channel layer CL includes, for example, silicon. The silicon in the channel layer CL may include donor impurities such as phosphorus (P) or acceptor impurities such as boron (B); alternatively, it may not include such impurities.

The diffusion layers DL1 and DL2 are semiconductor layers that extend in the XY plane. The diffusion layers DL1 and DL2 include, for example, silicon that includes donor impurities such as phosphorus. The diffusion layer DL1 is provided at a position sandwiched between the interconnect layer LBI and the channel layer CL in the Y direction and is in contact with these two layers. The diffusion layer DL2 is provided in contact with the source line SL in such a manner as to surround the source line SL in the source line region SLR, and is in contact with the channel layer CL in the Y direction.

A planar structure composed of the channel layer CL and the diffusion layers DL1 and DL2 is provided for each of the semiconductor layers spaced apart in the Z direction. That is, in each of the stacked semiconductor layers, the channel layer CL and the diffusion layers DL1 and DL2 are provided, and these layers are stacked such that they overlap in the Z direction. The plurality of stacked diffusion layers DL1 are applied with a voltage from the bit lines BL corresponding to them, and may have different potentials. The plurality of stacked diffusion layers DL2 are electrically coupled together via the source line SL and have approximately the same potential.

The plurality of insulating pillars RP and the plurality of conductive pillars GP extend in the Z direction so as to intersect the stacked semiconductor layers, and partially overlap each other to form a plurality of pillar columns PL that are alternately coupled in a chain along the Y direction. For example, the plurality of insulating pillars RP and the plurality of conductive pillars GP are alternately arranged in a staggered manner along the Y direction. The number of rows made of the plurality of insulating pillars RP and the plurality of conductive pillars GP may vary depending on the number of word lines WL and the number of select gate lines SGD and SGS. In the channel layer CL, a plurality of linear portions divided in the X direction by the pillar columns PL are referred to as channels CH. The channels CH function as channels of the NAND strings NS.

Each insulating pillar RP includes an insulator 40 having a first portion 40-1 and a plurality of second portions 40-2. The first portion 40-1 of the insulator 40 has either a cylindrical or elliptical cylindrical structure extending in the Z direction, or a truncated cone or elliptical truncated cone structure with a side surface tapered toward the semiconductor substrate. The first portion 40-1 of the insulator 40 corresponds to the region enclosed by the dashed line in FIG. 4. In the description below, reference will be made to the case where the first portion 40-1 of the insulator 40 has a truncated cone shape. In the plan shown in FIG. 4, the first portion 40-1 of the insulator 40 is shown as a circle with a radius R1. Each second portion 40-2 of the insulator 40 is a portion that extends radially in the XY plane at the locations where the insulating pillar RP intersects each semiconductor layer in the Z direction. The second portion 40-2 of the insulator 40 corresponds to the area outside the region enclosed by the dashed line in FIG. 4. Specifically, in the XY plane including a semiconductor layer, the cross-section of the corresponding second portion 40-2 of the insulator 40 has a ring shape formed by removing a circle of radius R1 from a circle of radius R2 (where R2>R1). The second portions 40-2 of each insulator 40 are provided for each of the semiconductor layers. However, the insulator 40 in each insulating pillar RP has a shape in which the portions at the locations where the insulator 40 overlaps the plurality of conductive pillars GP in the Z direction are omitted. The insulator 40 includes, for example, silicon oxide. The silicon oxide included in the insulator 40 may be doped with impurities such as phosphorus (P) or nitrogen (N).

Each of the plurality of conductive pillars GP includes a conductive film 30 and an insulating film 31. The conductive film 30 includes, for example, tungsten (W), molybdenum (Mo), titanium nitride (TiN), or silicon doped with phosphorus. The conductive film 30 has a cylindrical or elliptical cylindrical shape, or has a truncated cone or elliptical truncated cone shape with a side surface tapered toward the semiconductor substrate. The insulating film 31 includes, for example, silicon oxide (SiO), silicon nitride (SiN), aluminum oxide (AlO), or hafnium oxide (HfO), and is composed of a single layer or a plurality of layers. The insulating film 31 is provided so as to cover the side of the conductive film 30. In the description below, reference will be made to the case where the conductive film 30 and the insulating film 31 have a truncated cone shape. In the plan shown in FIG. 4, the shape of the combination of the conductive film 30 and the insulating film 31 is shown as a circle with a radius R3. For example, R3 is approximately the same length as R1. The lengths of R1 and R3 may be different. Some of the conductive pillars GP include a functional film 32. The functional film 32 is arranged between the insulating film 31 of the corresponding conductive pillar GP and each semiconductor layer. The functional film 32 is not arranged between the insulating pillar RP and the conductive pillar GP. That is, the functional film 32 has an arch shape in a plan view. More specifically, in an XY plane including a semiconductor layer, the functional film 32 has an arch shape formed by subtracting a sector shape with radius R3 and the same central angle from a sector shape with radius R4 (where R4>R3). Two functional films 32 are provided for one conductive pillar GP. The two functional films 32 provided for one conductive pillar GP are insulated from each other by the insulating film 31 and the insulating pillar RP. In the description below, the conductive pillar GP that includes the functional film 32 will be referred to as a conductive pillar CGP, and the conductive pillar GP that does not include the functional film 32 will be referred to as a conductive pillar SGP. It should be noted that all conductive pillars GP may be conductive pillars CGP including a functional film 32. In this case, some of the conductive pillars CGP serve the same function as conductive pillars SGP described below.

The plurality of conductive pillars SGP are provided at positions corresponding to the conductive pillars GP located closest to the diffusion layer DL1 and to those located closest to the diffusion layer DL2 in the pillar column PL (i.e., at the Y-direction ends of the pillar column PL). In the example shown in FIG. 4, each pillar column PL has one conductive pillar SGP provided at each end, i.e., at the end on the diffusion layer DL1 side and at the end of the DL2 side. However, a plurality of conductive pillars SGP may be provided instead. In each channel CH, each of the portions where the conductive pillars SGP provided on the diffusion layer DL1 side included in two adjacent pillar columns PL are in contact with the channel CH functions as a select transistor ST1. In each channel CH, each of the portions where the conductive pillars SGP provided on the diffusion layer DL2 side included in the two adjacent pillar columns PL are in contact with the channel CH functions as a select transistor ST2. That is, in each channel, a combination of voltages applied to the conductive pillars SGP included in the two adjacent pillar columns PL determines whether the NAND string NS including that channel is in a selected state or a non-selected state.

The plurality of conductive pillars CGP are provided at positions corresponding to the conductive pillars GP located in the central region of the pillar column PL (i.e., not at the Y-direction ends). The plurality of conductive pillars CGP are arranged, for example, side by side at a position sandwiched in the Y-direction between two conductive pillars SGP provided at the Y-direction ends of each pillar column PL. The portions where the plurality of conductive pillars CGP are in contact with the channel CH function as memory cell transistors MT0 to MT7.

In the example shown in FIG. 4, in the channel layer CL, one channel CH and four conductive pillars SGP and eight conductive pillars CGP that are in contact with that channel CH function as one NAND string NS.

A portion of the conductive pillar SGP located at the end of each pillar column PL on the diffusion layer DL1 side overlaps the diffusion layer DL1 in the Z direction. A portion of the conductive pillar SGP located at the end of each pillar column PL on the diffusion layer DL2 side overlaps the diffusion layer DL2 in the Z direction. By providing the conductive pillar SGP at the position that overlaps the diffusion layer DL1 or DL2 in the Z direction, the electrical resistance at the contact point between the conductive pillar SGP and the channel CH can be reduced when the select transistor ST1 or ST2 operates. In each NAND string NS, at least one conductive pillar SGP overlapping the diffusion layer DL1 in the Z direction and at least one conductive pillar SGP overlapping the diffusion layer DL2 in the Z direction are provided.

The plurality of contacts MPP are provided one for each of the plurality of conductive pillars GP. Among these, the contact MPP corresponding to the conductive pillar SGP extends in the Z direction, is in contact with the conductive film 30 of the conductive pillar SGP at its lower face, and is in contact with the corresponding select gate line SGD or SGS at its upper face. The contact MPP corresponding to the conductive pillar CGP extends in the Z direction, is in contact with the conductive film 30 of the conductive pillar CGP at its lower face, and is in contact with the corresponding word line WL at its upper face.

The plurality of insulating pillars LB include an insulator (e.g., silicon oxide). In addition, during the manufacture of the memory cell array 10, holes provided at positions corresponding to the plurality of insulating pillars LB are used to form the interconnect layer LBI and the diffusion layer DL1.

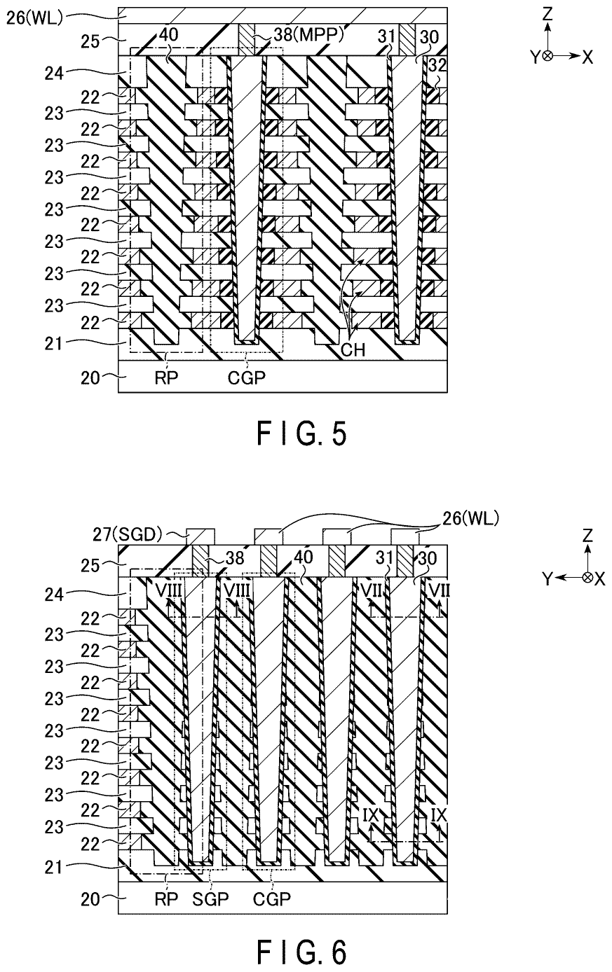

FIGS. 5 and 6 are cross-sectional views illustrating an example of the cross-sectional structure in the memory cell region of the memory cell array provided in the semiconductor memory device according to the embodiment. FIGS. 5 and 6 illustrate cross sections taken along lines V-V and VI-VI in FIG. 4, respectively. As shown in FIGS. 5 and 6, the memory cell array 10 further includes a semiconductor substrate 20, insulating layers 21, 23, 24 and 25, semiconductor layers 22, interconnect layers 26 and 27, and a plurality of conductors 38.

The insulating layer 21 is stacked above the semiconductor substrate 20, and on top of that, the plurality of semiconductor layers 22 and the plurality of insulating layers 23 are alternately stacked. Each semiconductor layer 22 is formed in a plate shape extending in the XY plane. The insulating layers 24 and 25 are stacked in this order above the uppermost semiconductor layer 22. Each semiconductor layer 22 corresponds to a channel layer CL. The plurality of insulating layers 21, 23, 24 and 25 include, for example, silicon oxide (SiO). The film type (material) included in the plurality of insulating layers 21, 23 and 24 and the film type (material) included in the insulator 40 is different. Note that, the film type included in the plurality of insulating layers 21, 23 and 24 and the film type included in the insulator 40 may be the same.

A plurality of interconnect layers 26 and 27 are provided above the insulating layer 25. The plurality of interconnect layers 26 are provided above the conductive pillars CGP in correspondence to the conductive pillars CGP, and are aligned along the Y direction. The plurality of interconnect layers 26 are used as word lines WL. The plurality of interconnect layers 27 are provided above the conductive pillars SGP in correspondence to the conductive pillars SGP, and are aligned along the Y direction. The plurality of interconnect layers 27 are used as select gate lines SGD and SGS. The plurality of interconnect layers 26 and 27 include, for example, tungsten (W).

The plurality of conductors 38 are provided inside the insulating layer 25 to extend in the Z direction. Each conductor 38 is provided in correspondence to the conductive pillars CGP and SGP, is in contact with the conductive film 30 of the conductive pillar CGP or SGP at its lower face, and is in contact with the corresponding wiring layer 26 or 27 at its upper face. The plurality of conductors 38 function as contacts MPP that couple the word line WL and the conductive pillar CGP to each other, or couple the select gate lines SGD and SGS and the conductive pillar SGP to each other.

As shown in FIG. 5, the semiconductor layer 22 is located between the insulating pillars RP and the conductive pillars CGP or SGP adjacent thereto in the X direction. This portion of the semiconductor layer 22 corresponds to the channel CH and functions as the channel of the NAND string NS.

As shown in FIG. 6, the semiconductor layer 22 is not arranged between the insulating pillars RP and the conductive pillars CGP or SGP adjacent to each other in the Y direction. That is, each channel CH in each NAND string NS is isolated from the channels CH adjacent in the X-direction.

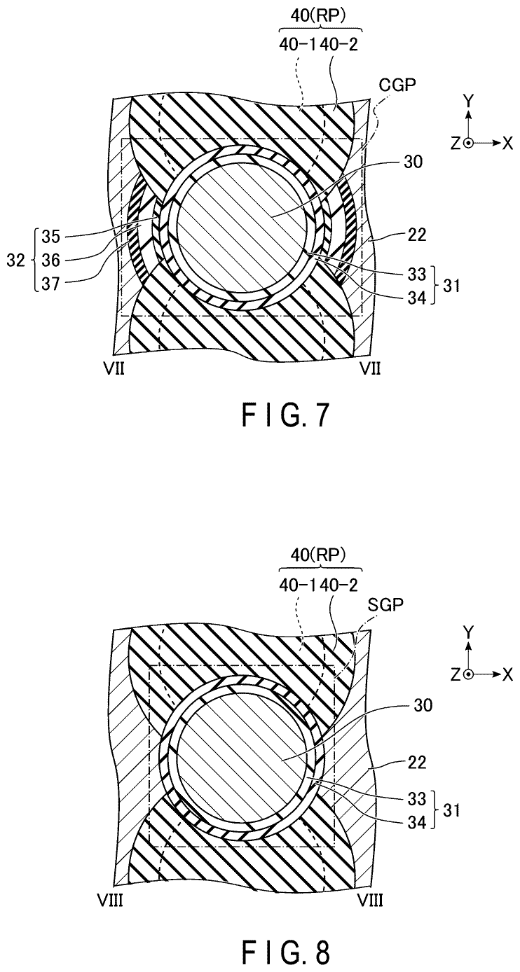

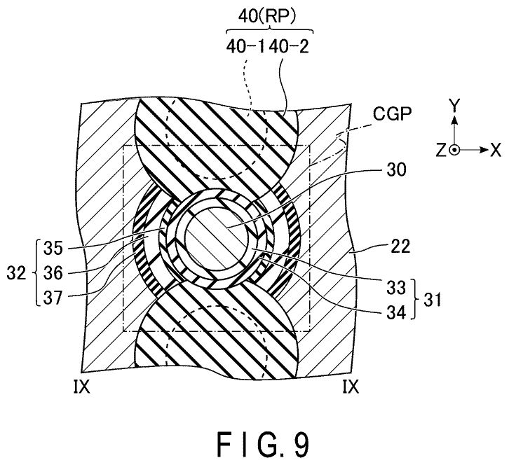

FIGS. 7, 8 and 9 are cross-sectional views illustrating an example of the cross-sectional structure of a conductive pillar provided in the semiconductor memory device according to the embodiment. FIG. 7 corresponds to a cross-sectional view of the conductive pillar CGP in a cross section taken along line VII-VII in FIG. 6 and including the uppermost semiconductor layer 22. FIG. 8 corresponds to a cross-sectional view of the conductive pillar SGP in a cross section taken along line VIII-VIII in FIG. 6 and including the uppermost semiconductor layer 22. FIG. 9 corresponds to a cross-sectional view of the conductive pillar CGP in a cross section taken along line IX-IX in FIG. 6 and including the lowermost semiconductor layer 22. As shown in FIGS. 7, 8 and 9, the insulating film 31 includes block insulating films 33 and 34. Also, as shown in FIGS. 7 and 9, the functional film 32 includes a block insulating film 35, a charge storage film 36, and a tunnel insulating film 37.

In a cross section including the semiconductor layer 22, the conductive film 30 is provided, for example, in the center of the conductive pillars CGP and SGP. The block insulating film 33 surrounds the side faces of the conductive film 30. The block insulating film 33 includes, for example, aluminum oxide (AlO). The block insulating film 34 surrounds the side face of the block insulating film 33. The block insulating film 34 includes, for example, silicon oxide. With the above configuration, the conductive pillar SGP can function as the select transistor ST1 or ST2 at the portion that is in contact with the semiconductor layer 22.

In the conductive pillar CGP shown in FIGS. 7 and 9, the block insulating film 35 surrounds the side face of the block insulating film 34 that is not covered with the insulator 40. The block insulating film 35 includes, for example, hafnium oxide (HfO) or hafnium silicate (HfSiO). The charge storage film 36 surrounds the side face of the block insulating film 35. The charge storage film 36 has a function of storing charges and includes, for example, polysilicon. The tunnel insulating film 37 surrounds the side face of the charge storage film 36. The tunnel insulating film 37 includes, for example, silicon oxide. With the above configuration, the conductive pillar CGP can function as a memory cell transistor MT at the portion that is in contact with the semiconductor layer 22.

In a case where the insulating pillar RP and the conductive pillar GP have a tapered shape that tapers toward the semiconductor substrate 20, the cross-sectional diameters of the insulating pillar RP and the conductive pillar GP in the cross section including the uppermost semiconductor layer 22 may differ from the cross-sectional diameters of the insulating pillar RP and the conductive pillar GP in the cross section including the lowermost semiconductor layer 22. Specifically, in the cross section including the uppermost semiconductor layer 22, the conductive film 30 and the insulating film 31 have portions that overlap both the first and second portions 40-1 and 40-2 of the insulator 40 in the Z direction, as shown in FIGS. 7 and 8. In other words, in the cross section including the uppermost semiconductor layer 22, the conductive pillar GP is in contact with both the first and second portions 40-1 and 40-2 of the insulator 40. This means that in the upper portion of the stack of semiconductor layers, the pillar-shaped structure of the insulating pillar RP and the pillar-shaped structure of the conductive pillar GP overlap each other. On the other hand, in the cross section including the lowermost semiconductor layer 22, the conductive film 30 and the insulating film 31 do not have a portion that overlaps the first portion 40-1 of the insulator 40 in the Z direction, but have a portion that overlaps only the second portions 40-2 in the Z direction, as shown in FIG. 9. In other words, in the cross section including the lowermost semiconductor layer 22, the conductive pillar GP is not in contact with the first portion 40-1 of the insulator 40 but is in contact with the second portions 40-2 of the insulator 40. This means that in the lower portion of the stack of semiconductor layers, the pillar-shaped structure portion of the insulating pillar RP and the pillar-shaped structure portion of the conductive pillar GP do not overlap each other.

As can be seen from the above, in a case where the insulating pillar RP and the conductive pillar GP have a tapered shape that tapers toward the semiconductor substrate 20, the first portion 40-1 of the insulator 40, which is the pillar-shaped structure portion of the insulating pillar RP, may not sufficiently insulate channels CH adjacent in the X direction. As a countermeasure, the second portions 40-2 of the insulator 40, which have a ring-shaped structure, are provided to divide the semiconductor layers 22 and ensure insulation between channels CH adjacent in the X direction.

The radial length of the second portions of the insulator 40 (i.e., the ring width of the ring-shaped structure) is designed to satisfy the following conditions: in the cross section including the lowermost semiconductor layer 22, the channel CH formed in the semiconductor layer 22 overlaps, in the Z direction, the conductive pillar GP adjacent in the Y direction; and in the cross section including the uppermost semiconductor layer 22, the channel CH, which is positioned between the conductive pillars GP adjacent in the X direction, has a sufficient width in the X direction to allow current to flow for various operations. Furthermore, the Y-direction spacing between the insulating pillars RP or conductive pillars GP in the pillar column PL, and the spacing between the pillar columns PL adjacent in the X direction are determined to satisfy the above conditions.

If the insulating pillar RP and the conductive pillar GP do not have a tapered shape or the taper angle is sufficiently small, the pillar-shaped structures overlap in the Z direction even in the lower portion of the stack of semiconductor layers. In such a case, the structure corresponding to the second portions 40-2 of the insulator 40 can be omitted.

### 2. Manufacturing Method

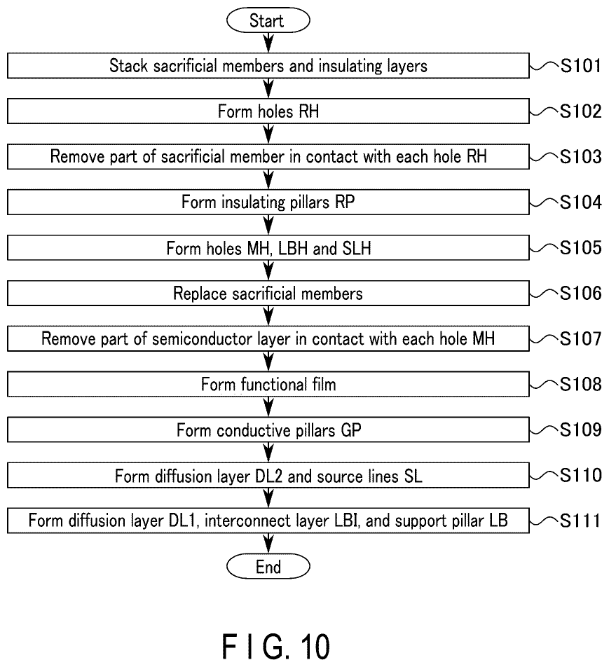

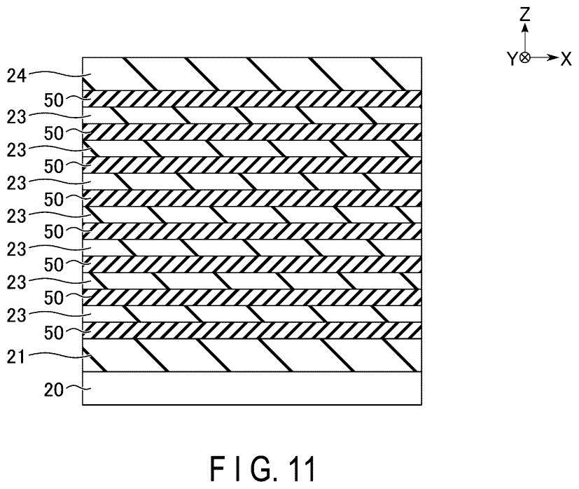

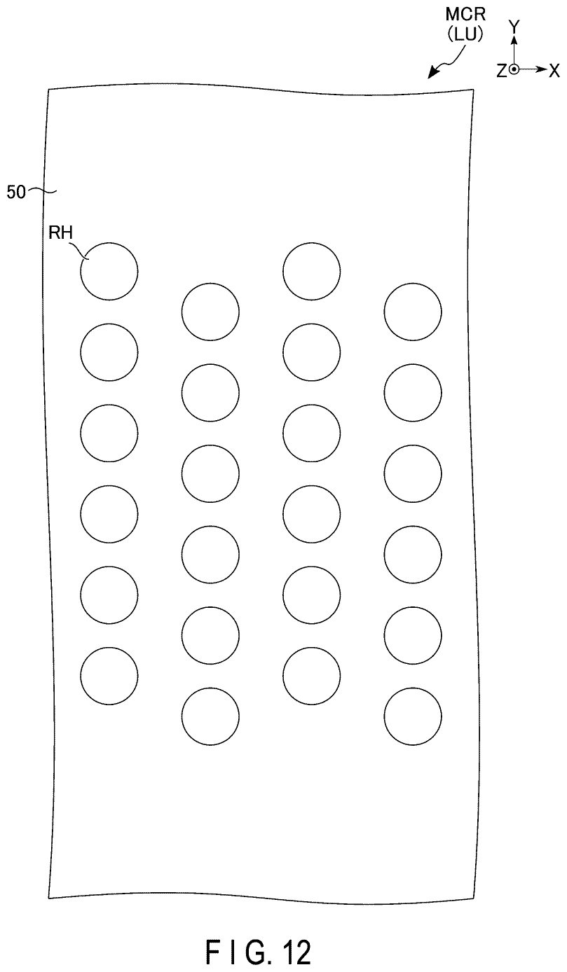

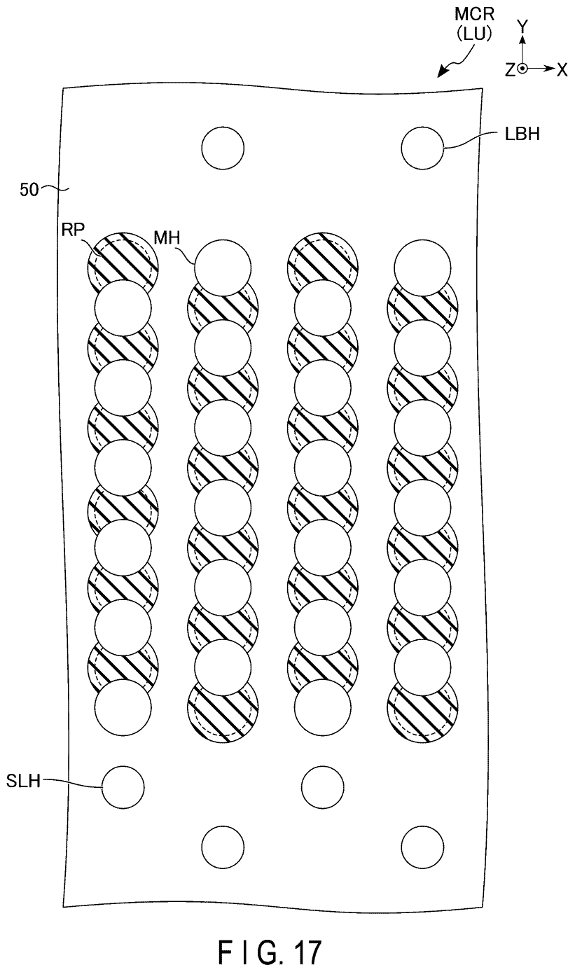

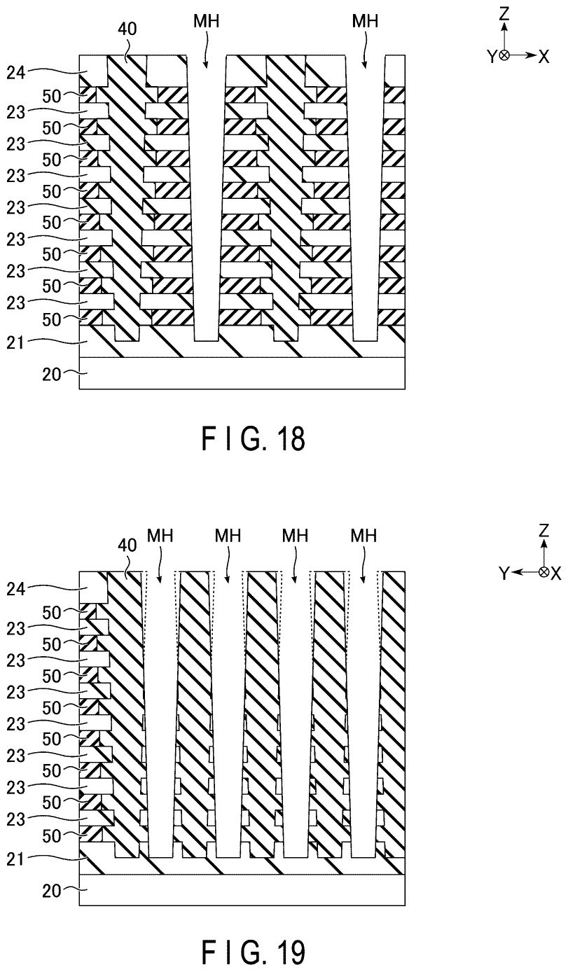

A description will be given of an example of a manufacturing process of the structure of the memory cell region of the memory cell array provided in the semiconductor memory device according to the embodiment. FIG. 10 is a flowchart illustrating an example of the manufacturing process of the memory cell region of the memory cell array provided in the semiconductor memory device according to the embodiment. FIGS. 11 to 25 are plan views or cross-sectional views illustrating an example of the planar layout or cross-sectional structure of the memory cell region during the manufacturing process of the memory cell array provided in the semiconductor memory device according to the embodiment. FIGS. 12 and 17 are plan views corresponding to the XY plane of the memory cell array 10 shown in FIG. 4. FIGS. 11, 13 to 15, 18 and 20 to 24 are cross-sectional views corresponding to the XZ cross section of the memory cell array 10 shown in FIG. 5. FIGS. 16, 19 and 25 are cross-sectional views corresponding to the YZ cross section of the memory cell array 10 shown in FIG. 6.

As shown in FIG. 10, in the manufacturing process of the memory cell region MCR, the processes of S101 to S111 are executed in order. An example of the manufacturing process of the memory cell region MCR will be described, referring to FIGS. 11 to 25 as appropriate.

In connection with the present embodiment, a method (hereinafter referred to as “replacement”) will be described, in which the semiconductor layers 22 are formed by first forming structures corresponding to the respective semiconductor layers 22 using sacrificial members 50, and then replacing the sacrificial members 50 with a semiconductor material.

First, the process of S101 is performed to form a stacked structure of semiconductor layers as shown in FIG. 11. Specifically, an insulating layer 21 is first stacked on a semiconductor substrate 20, and then sacrificial members 50 and insulating layers 23 are stacked one layer at a time on top of the insulating layer 21. The plurality of sacrificial members 50 include, for example, silicon nitride (SiN). An insulating layer 24 is stacked above the uppermost sacrificial member 50.

Next, the processes of S102 to S104 are performed to form an insulating pillar RP.

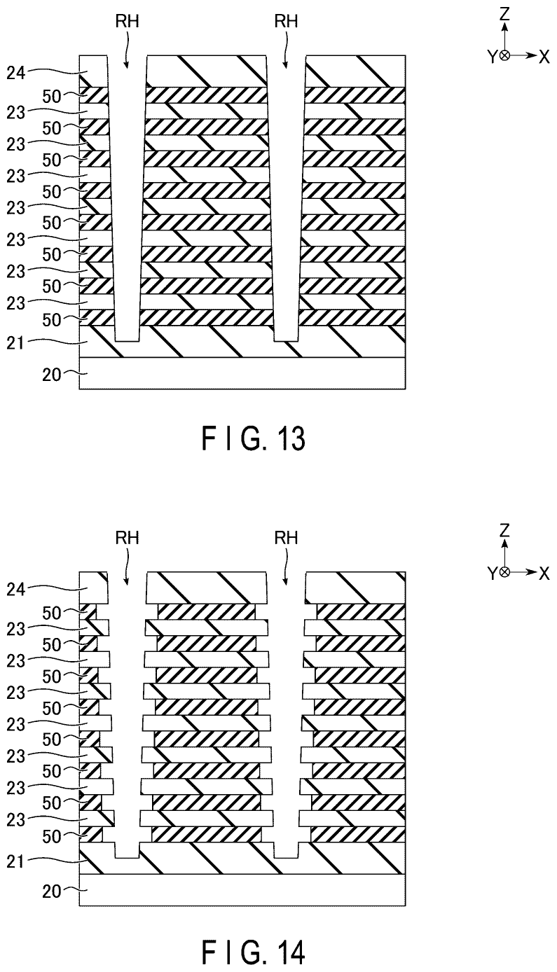

First, as shown in FIG. 12 and FIG. 13, holes RH are formed (S102). Specifically, a mask having an opening corresponding to the insulating pillar RP is formed by photolithography or the like. Then, a plurality of holes RH are formed by performing anisotropic etching using the mask. The plurality of holes RH penetrate the plurality of insulating layers 23, the insulating layer 24, and the plurality of sacrificial members 50. Part of the insulating layer 21 is exposed at the bottom of each hole RH.

Next, as shown in FIG. 14, the peripheral portion of the sacrificial member 50 exposed on the sidewall of each hole RH is removed by performing wet etching through the holes RH (S103). Thus, a plurality of grooves are formed on the sidewall of each hole RH, in which the sacrificial member 50 is recessed radially in the XY plane direction relative to the insulating layers 21, 23, and 24.

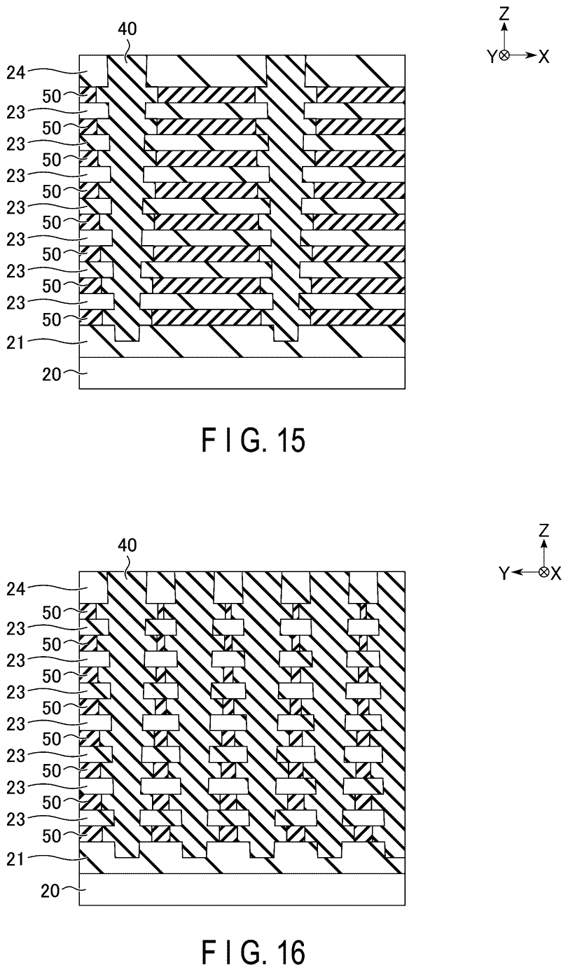

Then, as shown in FIGS. 15 and 16, an insulator 40 is embedded in each hole RH to form insulating pillars RP (S104). The insulator 40 is in contact with the sacrificial members 50 in the lateral direction at the plurality of grooves, and is also in contact with the insulating layer 21 at its bottom. At this time, the insulator 40 embedded in the plurality of holes RH formed in S102 corresponds to the first portion 40-1, and the insulator 40 embedded in the plurality of grooves formed in S103 corresponds to the second portions 40-2. In the example shown in FIG. 16, the sacrificial member 50 remains between the insulating pillars RP adjacent in the Y direction, but the insulators 40 corresponding to the insulating pillars RP adjacent in the Y direction may be in contact with each other. It should be noted that a sufficient gap is arranged between the insulating pillars RP adjacent in the X direction, and the sacrificial member 50 is interposed between them. Then, the insulator 40 formed on the upper face of the insulating layer 24 is removed, for example, by CMP (Chemical Mechanical Polishing).

Subsequently, the processes S105 to S109 are sequentially performed, and a plurality of conductive pillars SGP and CGP are formed.

First, a plurality of holes MH, LBH and SLH are formed (S105), as shown in FIGS. 17 to 19. Specifically, a mask is formed by photolithography or the like such that the mask has openings corresponding to the conductive pillars SGP and CGP, the insulating pillar LB, and the source line SL. Then, a plurality of holes MH, LBH and SLH are formed by executing anisotropic etching using the mask. At this time, each hole MH is formed in a chain-like manner along the Y-direction with the insulating pillars RP arranged in a row, and partially overlaps adjacent insulating pillars RP. Each of the dotted line portions in FIG. 19 is the region where the first portion 40-1 of the insulator 40 was provided, i.e., the region where the hole RH was provided. As shown in FIG. 19, the plurality of holes RH and MH are provided at positions where they partially overlap each other in the upper portion of the stack of semiconductor layers. The plurality of holes MH, LBH and SLH penetrate the plurality of insulating layers 23, the insulating layer 24 and the plurality of sacrificial members 50. At the bottom of each of the holes MH, LBH and SLH, a portion of the insulating layer 21 is exposed. Then, the holes MH corresponding to the conductive pillars SGP, as well as the holes LBH and SLH, are filled with a sacrificial material.

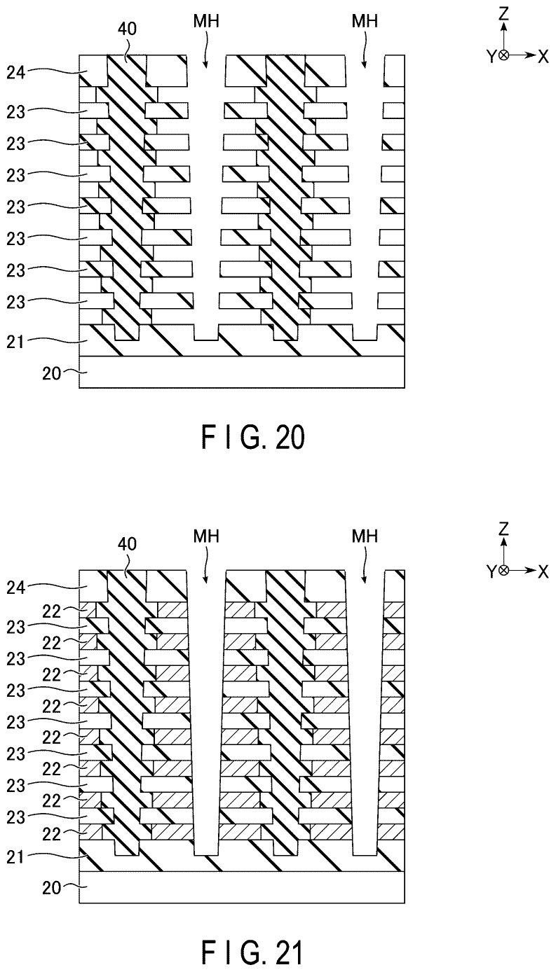

Next, the sacrificial material 50 is replaced (S106). Specifically, as shown in FIG. 20, the sacrificial material 50 around the holes MH is removed by executing wet etching or the like through the holes MH. The three-dimensional structure of the memory cell array 10 is supported by the plurality of insulating pillars RP. Then, as shown in FIG. 21, the regions from which the sacrificial material 50 has been removed are filled (replaced) with a semiconductor material through the holes MH. For example, CVD (Chemical Vapor Deposition) is used to form the semiconductor layers in the present process. Then, the semiconductor material formed inside the holes MH is removed by an etch-back process, and the semiconductor layers 22 adjacent in the Z direction are separated from each other.

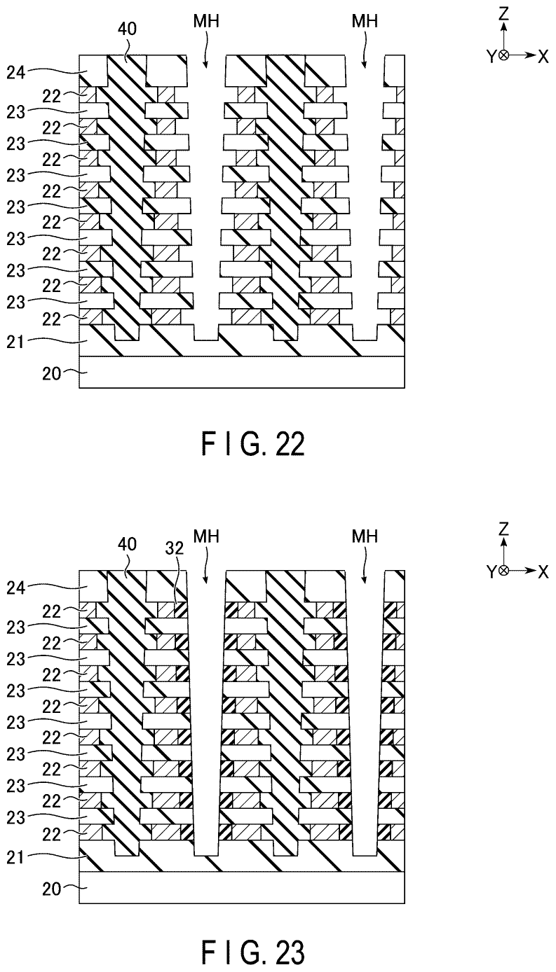

Next, as shown in FIG. 22, the peripheral portion of the semiconductor layer 22 exposed on the sidewall of each hole MH is removed by executing wet etching or the like through the holes MH (S107). Thus, a plurality of grooves are formed along the sidewall of each hole MH, whereby the semiconductor layer 22 is recessed radially in the XY plane relative to the insulating layers 21, 23, and 24.

Next, as shown in FIG. 23, a functional film 32 is formed in the plurality of grooves formed in S107 (S108). Specifically, a tunnel insulating film 37, a charge storage film 36, and a block insulating film 35 are formed in this order on the sidewall of each hole MH, and the functional film 32 is formed thereby. Then, the functional film 32 formed inside each hole MH is removed by an etch-back process. At this time, the functional film 32 formed in the plurality of grooves is not removed. The functional film 32 is formed in an arch shape and is in contact with the semiconductor layer 22 at its side.

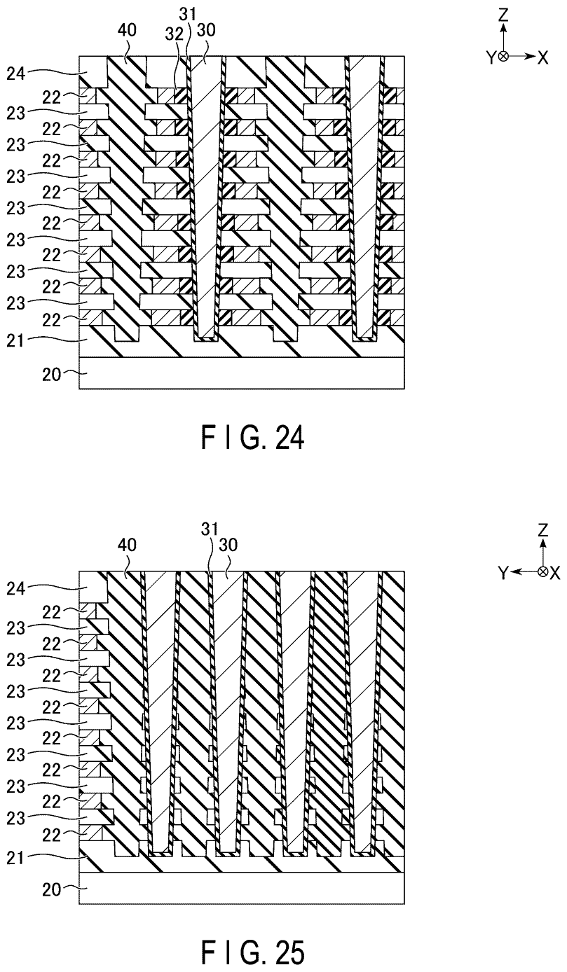

Thereafter, as shown in FIGS. 24 and 25, an insulating film 31 and a conductive film 30 are embedded in each hole MH to form conductive pillars GP (S109). Specifically, block insulating films 34 and 33 are formed in this order inside each hole MH to form an insulating film 31. Subsequently, a conductive film 30 is formed in such a manner as to embed each hole MH. The insulating film 31 is in contact with the insulating layer 21 at its bottom face and is in contact with the functional film 32 at part of its side face. The conductive film 30 is in contact with the insulating film 31 at its bottom face and side face. Finally, the conductive film 30 formed on the upper face of the insulating layer 24 is removed, for example, by CMP to expose the face corresponding to the upper end of the conductive pillar CGP.

The conductive pillar SGP is formed in a process similar to that of S109 after the conductive pillar CGP is formed and the sacrificial member provided in the hole MH corresponding to the conductive pillar SGP is removed. If the sacrificial member 50 remains in a portion adjacent to the hole MH corresponding to the conductive pillar SGP, a process corresponding to S106 may be performed before the process of S109.

Thereafter, a diffusion layer DL2 and a plurality of source lines SL are formed (S110). Specifically, the sacrificial members embedded in the plurality of holes SLH are first removed. Then, the sacrificial members 50 around the plurality of holes SLH are removed through the holes SLH. At this time, the plurality of semiconductor layers 22 are exposed on the sidewalls of the grooves from which the sacrificial members 50 have been removed. Next, silicon containing donor impurities such as phosphorus is embedded (replaced) through the plurality of holes SLH in the regions from which the sacrificial members 50 have been removed. Then, the silicon formed inside the hole SLH is removed by an etch-back process, and the semiconductor layers 22 adjacent in the Z direction are separated from each other. This forms a structure corresponding to the diffusion layer DL2. Then, a metal containing, for example, tungsten is filled into the plurality of holes SLH. This forms a structure corresponding to the source line SL. Before the holes SLH are filled with metal, the sidewalls of the plurality of holes SLH may be coated with titanium nitride, for example.

Thereafter, a diffusion layer DL1, an interconnect layer LBI, and an insulating pillar LB are formed (S111). Specifically, the sacrificial members filled into the holes LBH are first removed. Then, the sacrificial members 50 remaining around the plurality of holes LBH are removed through the holes LBH. At this time, the plurality of semiconductor layers 22 are exposed on the sidewall of the groove from which the sacrificial members 50 have been removed. Next, silicon containing donor impurities such as phosphorus is filled (replaced) through the holes LBH in the region from which the sacrificial members 50 have been removed. Then, the silicon formed inside the holes LBH is removed by an etch-back process, the semiconductor layers 22 adjacent in the Z direction are separated from each other, and the silicon provided in the region corresponding to the interconnect layer LBI is removed. This forms a structure corresponding to the diffusion layer DL1. A conductor containing, for example, titanium nitride is then formed in the region from which the silicon has been removed. The conductor formed inside the hole LBH is then removed by an etch-back process, and the semiconductor layers 22 adjacent in the Z direction are separated from each other. Thus, a structure corresponding to the interconnect layer LBI is formed. Finally, an insulator including, for example, silicon oxide is filled into the hole LBH. Thus, a structure corresponding to the insulating pillar LB is formed.

### 3. Advantages of Embodiment

According to the present embodiment, the integration density of the semiconductor memory device can be improved. This advantage will be described in detail below.

In the memory cell array 10 according to the present embodiment, the conductive pillar GP is in contact with two channels CH that are adjacent in the X direction, and functions as either a memory cell transistor MT or a select transistor ST1 or ST2 at each contact point. Compared with a configuration in which one conductive pillar corresponds to only one channel, the structure of the present embodiment allows for a shorter distance between adjacent channels CH in the X direction, and therefore improves the integration density of the semiconductor memory device 3.

In addition, in the memory cell array 10 according to the present embodiment, the plurality of channels CH are divided and insulated in the X direction by the plurality of pillar columns PL. Each pillar column is composed of a plurality of insulating pillars RP and a plurality of conductive pillars GP, and these pillars support the structure of the memory cell array 10 and suppress deformation of the memory cell array 10 due to stress during the manufacturing process. In addition, in the manufacturing process of the pillar columns PL, a plurality of holes RH corresponding to a plurality of insulating pillars RP are first formed, and after the plurality of holes RH are filled with an insulator 40, a plurality of holes MH corresponding to a plurality of conductive pillars GP are formed. In this manner, in the memory cell array 10 according to the present embodiment, the structure that separates channels adjacent in the X direction is formed in two stages: the formation of a structure corresponding to a plurality of insulating pillars RP, and the formation of a structure corresponding to a plurality of conductive pillars GP. Compared with a structure in which a trench dividing the channel is formed and is then filled with an insulator after replacement, deformation of the channel layer CL in the X direction is reduced, thereby suppressing its bending. Therefore, it is not necessary to include an additional structure to suppress deformation of the memory cell array 10 and bending of the channel layer CL. As a result, the chip area required for such a structure can be reduced, leading to improved integration density of the semiconductor memory device 3. Furthermore, since the process of forming the additional structure can be omitted in the manufacturing process, an increase in production cost can be suppressed.

### 4. Others

The semiconductor memory device 3 according to the embodiment described above can be modified in various manners. The first and second modifications of the embodiment will be described below in terms of the differences from the embodiment.

### 4.1 First Modification

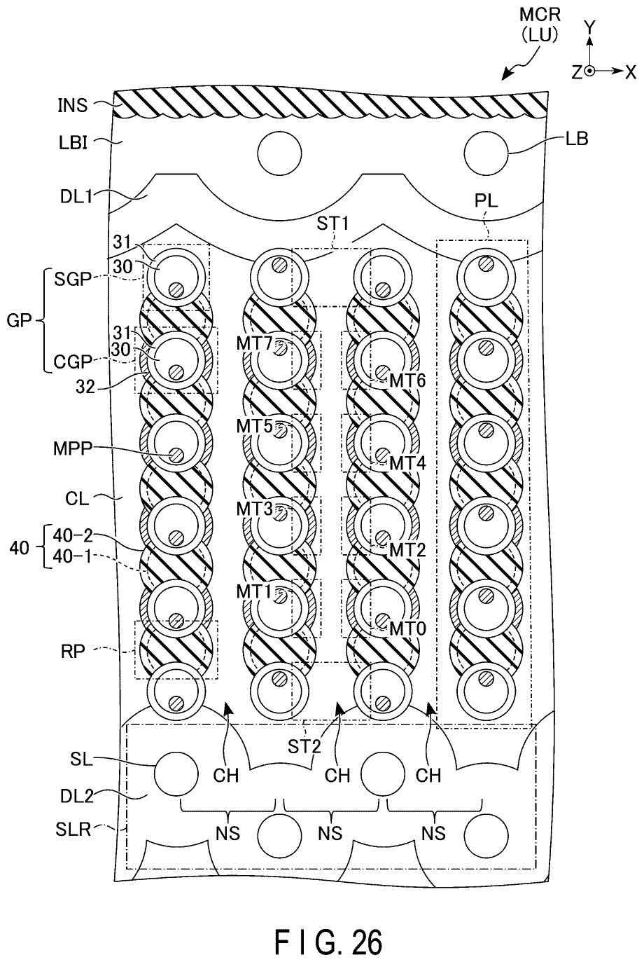

FIG. 26 is a plan view illustrating an example of the planar layout in a memory cell region of a memory cell array provided in a semiconductor memory device according to the first modification of the embodiment.

As shown in FIG. 26, the memory cell array 10 provided in the semiconductor memory device 3 according to the first modification is arranged in a lattice pattern such that the insulating pillars RP and conductive pillars GP provided in the pillar columns PL are aligned in the same rows in the X direction. For example, the plurality of conductive pillars GP arranged in the X direction are alternately coupled to the same word line WL or to the select gate lines SGD and SGS. For instance, at both ends of each pillar column PL, a conductive pillar SGP corresponding to the select gate line SGD and a conductive pillar SGP corresponding to the select gate line SGS are provided.

According to the first modification of the embodiment, the integration density of the semiconductor memory device can be improved, as in the embodiment.

### 4.2 Second Modification

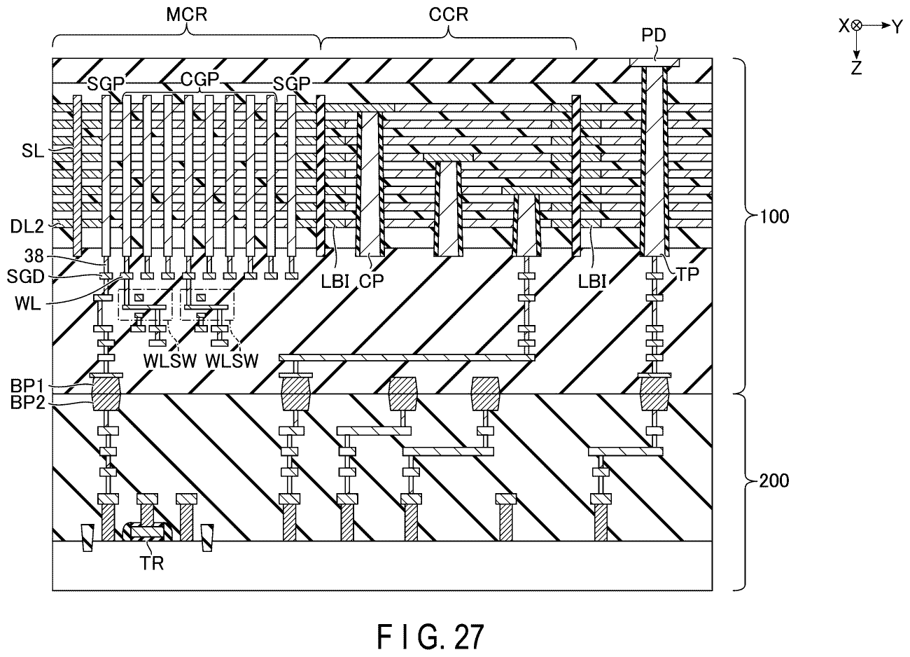

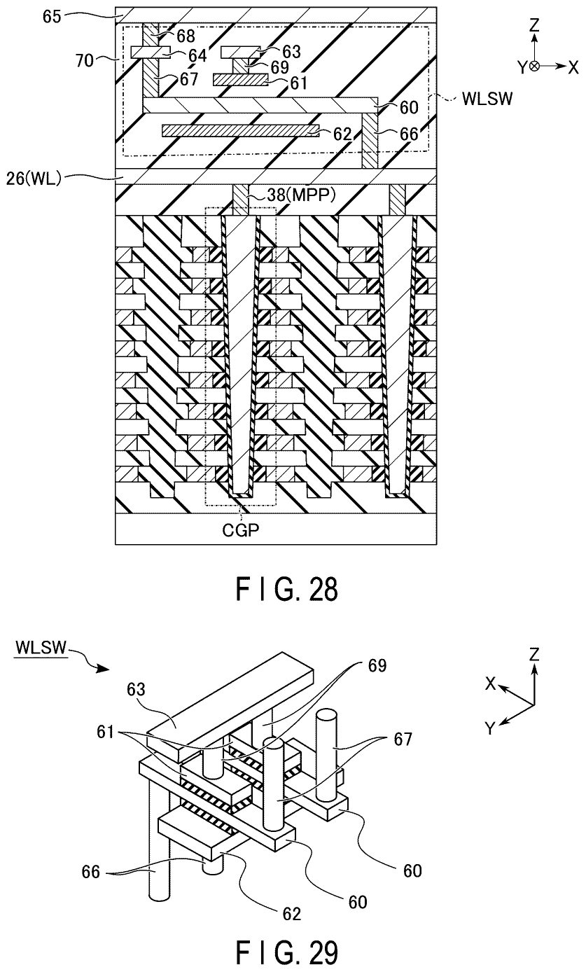

FIG. 27 is a cross-sectional view illustrating an example of the cross-sectional structure of a semiconductor memory device according to the second modification of the embodiment. In FIG. 27, the Z direction is shown extending downward relative to the drawing sheet. In FIG. 27, illustration of the insulating pillar RP and some of the configurations is omitted. FIG. 28 is a cross-sectional view illustrating an example of the cross-sectional structure of a word line switch WLSW provided in the semiconductor memory device according to the second modification of the embodiment. FIG. 29 is a perspective view illustrating an example of the structure of the word line switch WLSW provided in the semiconductor memory device according to the second modification of the embodiment. In FIG. 29, illustration of part of the insulating layer 70 is omitted.

As shown in FIG. 27, the semiconductor memory device 3 according to the second modification of the embodiment has a bonded structure. In the semiconductor memory device 3 of the bonded structure, a memory chip 100 and a control circuit chip 200 are bonded in the Z direction. A control circuit including, for example, a CMOS circuit is formed in the control circuit chip 200. For example, part of the row decoder module 16, the sense amplifier module 17, the sequencer 14, etc. are formed in the control circuit chip 200.

The memory chip 100 includes, for example, a memory cell array 10, a plurality of word line switches WLSW, a conductive pillar TP, and a pad PD. The semiconductor memory device 3 according to the second modification of the embodiment has a structure in which a semiconductor substrate 20 has been removed. The semiconductor substrate 20 may be partially or entirely left in place.

The word line switch WLSW controls whether or not to drive the word line WL provided in the corresponding layer unit LU. In other words, in a case where a certain layer unit LU is selected, the corresponding word line switch WLSW is turned on. In a case where the certain layer unit LU is not selected, the corresponding word line switch WLSW is turned off. The structure of the word line switch WLSW will be described with reference to FIG. 28.

As shown in FIG. 28, the memory chip 100 provided in the semiconductor memory device 3 according to the second modification of the embodiment further includes a semiconductor layer 60, conductive layers 61 and 62, interconnect layers 63, 64 and 65, contacts 66, 67, 68 and 69, and an insulating layer 70. Of these components, the semiconductor layer 60 and the conductive layers 61 and 62 correspond to part of a transistor functioning as a word line switch WLSW.

The semiconductor layer 60 includes, for example, polysilicon. The semiconductor layer 60 extends, for example, in the X direction, with one end coupled to an interconnect layer 26 via the contact 66 and the other end coupled to the interconnect layer 65 via the interconnect layer 64 and the contacts 67 and 68. In a case where the potential difference between the conductive layers 61 and 62 is large, the semiconductor layer 60 electrically couples the two conductive layers. The semiconductor layer 60 serves as a channel in the transistor. The conductive layer 61 is used as a gate electrode of the transistor. The conductive layer 61 is coupled to the interconnect layer 63 via the contact 69. The conductive layer 62 is used as a back gate electrode of the transistor. As shown in FIG. 29, the conductive layer 62 can be commonly provided within the same layer unit LU. The conductive layers 61 and 62 include, for example, silicon or metal. The interconnect layer 63 may be commonly provided within the same layer unit LU, as shown in FIG. 29. A voltage for controlling the driving of the word line switch WLSW is applied to the interconnect layer 63. The interconnect layer 64 couples the semiconductor layer 60 and the interconnect layer 65 to each other. The interconnect layer 65 functions as a global word line. The interconnect layer 65, which is coupled to the row decoder module 16 in a region not shown, receives the voltage applied to the word line WL. The interconnect layer 65 is commonly provided within the same block BLK. The contact 66 extends in the Z direction through the insulating layer 70 and couples the semiconductor layer 60 and the interconnect layer 26 to each other. The contact 67 extends in the Z direction through the insulating layer 70 and couples the semiconductor layer 60 and the interconnect layer 64 to each other. The contact 68 extends in the Z direction through the insulating layer 70 and couples the interconnect layers 64 and 65 to each other. The contact 69 extends in the Z direction through the insulating layer 70 and couples the conductive layer 61 and the interconnect layer 63 to each other. The insulating layer 70 provides insulation among each conductive layer, interconnect layer, and contact. Furthermore, the portion of the insulating layer 70 arranged between the conductive layer 61 and the semiconductor layer 60 and the portion of the insulating layer 70 arranged between the conductive layer 62 and the semiconductor layer 60 each function as a gate insulating film.

In a case where the layer unit LU is selected, a high voltage is applied to the interconnect layer 63. Thus, the semiconductor layer 60 becomes conductive, and the conductive pillar GP and the interconnect layer 65 in the layer unit LU are coupled to each other. This electrically couples the conductive pillar GP and the row decoder module 16, and reading or writing to the memory cell transistor MT is performed. On the other hand, in a case where the layer unit LU is not selected, the potential of the interconnect layer 63 becomes low. Thus, the semiconductor layer 60 becomes non-conductive, and the conductive pillar GP and the interconnect layer 65 in the layer unit LU are insulated from each other.

The conductive pillar TP is a pillar that is provided at the same height as the memory cell array 10 and penetrates the plurality of semiconductor layers 22 in the Z direction. The conductive pillar TP is insulated from each of the stacked structures of semiconductor layers and is coupled to the pad PD at its end. The pad PD is exposed to the outside on the surface of the semiconductor memory device 3. The pad PD is used to couple the semiconductor memory device 3 to a memory controller 2, etc. Although one conductive pillar TP and one pad PD are shown in FIG. 27, a plurality of conductive pillars TP and a plurality of pads PD may be provided in practice.

The control circuit chip 200 includes a transistor TR. Although one transistor TR is shown in FIG. 27, a plurality of transistors TR are provided in practice. The transistor TR constitutes, for example, the row decoder module 16 or the sense amplifier module 17.

The semiconductor memory device 3 includes a plurality of bonding pads BP1 and BP2 on the bonding surface to which the memory chip 100 and the control circuit chip 200 are attached. The plurality of bonding pads BP1 are formed on the memory chip 100. Some of the bonding pads BP1 are each coupled to one of the conductive pillars CGP, SGP and CP, the conductive pillar TP, etc., via interconnects. The plurality of bonding pads BP2 are formed on the control circuit chip 200. Some of the bonding pads BP2 are coupled to a plurality of transistors TR via interconnects. The bonding pads BP1 and BP2 include active pads, which are coupled to elements (such as interconnects), and dummy pads, which are not coupled to any elements. The bonding pads BP1 and BP2 are in contact with each other in the Z direction. Each active pad provides electrical coupling between the elements to which it is coupled. The bonding pads BP1 and BP2 include, for example, copper (Cu).

As a result of the above structure, a configuration in which the memory chip 100 and the control circuit chip 200 are bonded together is achieved.

According to the second modification of the embodiment, the integration density of the semiconductor memory device can be improved, as in the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
two first conductive pillars that extend in a first direction intersecting a substrate and that are aligned in a second direction intersecting the first direction;
a first semiconductor layer and a second semiconductor layer that are arranged in a first plane parallel to the substrate and that sandwich the two first conductive pillars in a third direction intersecting both the first direction and the second direction;
a first insulator that is arranged between the two first conductive pillars and that insulates the two first conductive pillars from each other, and further insulates the first semiconductor layer and the second semiconductor layer from each other in the first plane;
two first charge storage films that are arranged in the first plane between the two first conductive pillars and the first semiconductor layer, respectively; and
two second charge storage films that are arranged in the first plane between the two first conductive pillars and the second semiconductor layer, respectively,
wherein the first insulator includes a portion that is in contact with the first semiconductor layer and the second semiconductor layer in the first plane, and that is formed in a concentric circular or concentric elliptical shape having a center between the two first conductive pillars.

2. The semiconductor memory device according to claim 1, wherein the two first conductive pillars are formed such that a cross section in the first plane is circular or elliptical.

3. The semiconductor memory device according to claim 2, wherein in the first plane, the two first charge storage films and the two second charge storage films are formed in an arch shape along a cross-sectional shape of the two first conductive pillars.

4. The semiconductor memory device according to claim 1, further comprising:
a third semiconductor layer and a fourth semiconductor layer that are arranged between the substrate and the first plane, that are spaced apart from the first semiconductor layer and the second semiconductor layer in the first direction in a second plane parallel to the substrate, and that sandwich the two first conductive pillars in the third direction;
two third charge storage films that are arranged in the second plane between the two first conductive pillars and the third semiconductor layer, respectively; and
two fourth charge storage films that are arranged in the second plane between the two first conductive pillars and the fourth semiconductor layer, respectively,
wherein the first insulator includes:
a first portion that has a columnar structure extending in the first direction and that has a tapered shape tapering from the first plane toward the second plane, and a plurality of second portions that have a structure extending radially from the first portion toward the first plane and the second plane at a portion intersecting the first plane and the second plane, and
the first insulator is in contact with each of the third semiconductor layer and the fourth semiconductor layer in the third direction at the second plane and insulates the third semiconductor layer and the fourth semiconductor layer from each other, and
wherein a portion of the first insulator that is in contact with the third semiconductor layer and the fourth semiconductor layer is formed in a concentric circular or concentric elliptical shape having a center between the two first conductive pillars.

5. The semiconductor memory device according to claim 4, wherein each of the two first conductive pillars has a columnar structure extending in the first direction and having a tapered shape tapering from the first plane toward the second plane, and a cross section in the first plane and the second plane is formed into a circular or elliptical shape.

6. The semiconductor memory device according to claim 5, wherein each of the two first conductive pillars is in contact with the first portion and second portions of the first insulator in the first plane, and is in contact with only the second portions of the first insulator, and not with the first portion, in the second plane.

7. The semiconductor memory device according to claim 1, further comprising:
two second conductive pillars that extend in the first direction and intersect the first plane, and that are aligned in the second direction and sandwich the first semiconductor layer with the two first conductive pillars in the third direction;
a second insulator that is arranged between the two second conductive pillars and insulates the two second conductive pillars from each other; and
two fifth charge storage films that are arranged in the first plane between the two second conductive pillars and the first semiconductor layer, respectively,
wherein the second insulator includes a portion that is in contact with the first semiconductor layer in the first plane and that is formed in a concentric circular or concentric elliptical shape having a center between the two second conductive pillars.

8. The semiconductor memory device according to claim 7, wherein the two first conductive pillars and the two second conductive pillars are arranged in a staggered manner as viewed in the first direction, with the first semiconductor layer being interposed therebetween, and are alternately positioned in the third direction.

9. The semiconductor memory device according to claim 7, wherein the two first conductive pillars and the two second conductive pillars are arranged in a lattice pattern as viewed in the first direction, with the first semiconductor layer being interposed therebetween, and are located substantially at identical positions in the third direction.

10. The semiconductor memory device according to claim 7, wherein the first insulator is not in contact with either the two second conductive pillars or the second insulator, and
the second insulator is not in contact with either the two first conductive pillars or the first insulator.

11. The semiconductor memory device according to claim 1, further comprising:
a plurality of first conductive pillars that include the two first conductive pillars, that extend in the first direction, that are aligned in the second direction, and that are sandwiched in the third direction by the first semiconductor layer and the second semiconductor layer;
a plurality of first insulators that include the first insulator, that are arranged between the plurality of first conductive pillars, that insulate adjacent ones of the plurality of first conductive pillars from each other, and that insulate the first semiconductor layer and the second semiconductor layer from each other in the first plane;
a plurality of first charge storage films that include the two first charge storage films, and that are arranged in the first plane between the first conductive pillars and the first semiconductor layer, respectively; and
a plurality of second charge storage films that include the two second charge storage films, and that are arranged in the first plane between the plurality of first conductive pillars and the second semiconductor layer, respectively,
wherein each of the first insulators includes a portion that is in contact with the first semiconductor layer and the second semiconductor layer in the first plane, and that is formed in a concentric circular or concentric elliptical shape having a center located between two of the plurality of first conductive pillars adjacent to each other in the second direction, and
the plurality of first conductive pillars and the plurality of first insulators are arranged alternately in the second direction to form a pillar column.

12. The semiconductor memory device according to claim 1, further comprising:
a third conductive pillar and a fourth conductive pillar that are aligned with the two first conductive pillars in the second direction and sandwich the two first conductive pillars in the second direction, that extend in the first direction, and that are sandwiched in the third direction by the first semiconductor layer and the second semiconductor layer in the first plane;
a third insulator that is arranged between the third conductive pillar and the two first conductive pillars, and that insulates the third conductive pillar and the two first conductive pillars from each other, and further insulates the first semiconductor layer and the second semiconductor layer from each other in the first plane; and
a fourth insulator that is arranged between the fourth conductive pillar and the two first conductive pillars, and that insulates the third conductive pillar and the two first conductive pillars from each other and further insulates the first semiconductor layer and the second semiconductor layer from each other in the first plane.

13. The semiconductor memory device according to claim 12, further comprising:
a first diffusion layer and a second diffusion layer that are arranged in contact with each end of the first semiconductor layer and the second semiconductor layer respectively in the second direction and that sandwich the first semiconductor layer and the second semiconductor layer in the second direction,
wherein the third conductive pillar is in contact with the first diffusion layer, and
the fourth conductive pillar is in contact with the second diffusion layer.

14. The semiconductor memory device according to claim 13, wherein the first diffusion layer and the second diffusion layer include silicon doped with donor impurities.

15. The semiconductor memory device according to

13. further comprising:
a third semiconductor layer and a fourth semiconductor layer that are arranged between the substrate and the first plane, that are spaced apart from the first semiconductor layer and the second semiconductor layer in the first direction in a second plane parallel to the substrate, and that sandwich the two first conductive pillars, the third conductive pillar and the fourth conductive pillar in the third direction;
two third charge storage films that are arranged in the second plane between the two first conductive pillars and the third semiconductor layer, respectively;
two fourth charge storage films that are arranged in the second plane between the two first conductive pillars and the fourth semiconductor layer, respectively;
a third diffusion layer and a fourth diffusion layer that are arranged in contact with each end of the third semiconductor layer and the fourth semiconductor layer respectively in the second direction and that sandwich the third semiconductor layer and the fourth semiconductor layer in the second direction; and
a fifth conductive pillar that extends in the first direction, and that intersects the second diffusion layer in the first plane and intersects the fourth diffusion layer in the second plane,
wherein the second diffusion layer and the fourth diffusion layer are applied with a substantially equal voltage via the fifth conductive pillar.

16. The semiconductor memory device according to claim 15, further comprising:
a first interconnect layer having one end in contact with the first diffusion layer in the first plane; and
a second interconnect layer having one end in contact with the third diffusion layer in the second plane,
wherein the first interconnect layer and the second interconnect layer are electrically insulated from each other.

17. The semiconductor memory device according to claim 4, further comprising:
an insulating layer that is arranged between the first plane and the second plane, that extends in the second direction and the third direction, and that includes a first film type,
wherein the insulating layer insulates the first semiconductor layer and the third semiconductor layer from each other and further insulates the second semiconductor layer and the fourth semiconductor layer from each other,
the two first conductive pillars and the first insulator extend through the insulating layer in the first direction,
the first insulator includes a second film type different from the first film type.

18. The semiconductor memory device according to claim 17, wherein the insulating layer includes:
a portion sandwiched in the first direction between the two first charge storage films and the two third charge storage films;
a portion sandwiched in the first direction between the two second charge storage films and the two fourth charge storage films; and
a portion sandwiched in the first direction between the plurality of second portions of the first insulator.

19. The semiconductor memory device according to claim 17, wherein the second film type includes silicon oxide doped with impurities.

20. The semiconductor memory device according to claim 19, wherein the impurities in the second film type include phosphorus or nitrogen.
